(19) United States
(12) Patent Application Publication
(10) Pub. No.: US 2006/0138667 A1
(43) Pub. Date: Jun. 29, 2006

(54) Method for forming an intermetal dielectric layer in a semiconductor device using HDP-CVD, and a semiconductor device manufactured thereby

(75) Inventor: June Woo Lee, Osan-si (KR)

Correspondence Address: OBLON, SPIVAK, MCCLELLAND, MAIER & NEUSTADT, P.C., 1940 DUKE STREET, ALEXANDRIA, VA, 22314, US

(73) Assignee: DongbuAnam Semiconductor, Inc., Gangnam-gu (KR)

(21) Appl. No.: 11/320,396

(22) Filed: Dec. 29, 2005

(30) Foreign Application Priority Data
Dec. 29, 2004 (KR) 10-2004-0115786

(51) Int. Cl. H01L 23/52; H01L 21/469

(52) U.S. Cl. 257/760; 438/624; 438/669; 438/763

(57) ABSTRACT

A method for forming an intermetal dielectric layer in a semiconductor device using high density plasma chemical vapor deposition (HDP-CVD), and a semiconductor device manufactured thereby. The method includes the steps of: (a) forming a metal wiring including at least one via-hole by patterning a metal layer formed on a semiconductor substrate; (b) forming a nitride liner protecting the metal wiring; and (c) forming the intermetal dielectric layer on and between the metal wiring using HDP-CVD.

This application claims the benefit of Korean Application No. 10-2004-0115786, filed on Dec. 29, 2004, which is hereby incorporated by reference in its entirety.

### BACKGROUND OF THE INVENTION

1. Field of the Invention

The present invention relates to a semiconductor device manufacturing technology. More specifically, the present invention relates to a method for forming an intermetal dielectric layer in a semiconductor device using high density plasma chemical vapor deposition (HDP-CVD), and a semiconductor device manufactured thereby.

2. Description of the Related Art

As integration of a semiconductor device increases, a dimension of metal wiring is miniaturized more and more. Chemical vapor deposition (CVD), especially plasma enhanced chemical vapor deposition (PECVD) and spin-on grass (SOG) have been generally used for forming a multilevel-interconnection in semiconductor devices, such as a memory device, logic device, and so on. CVD involves depositing a thin film (e.g., a silicon oxide) on a target using chemical reaction of source gases. In the case of SOG, a liquefied silicon compound is applied and heat-treated on a substrate to be changed in the form of a silicon oxide. However, if a gap between adjacent metal wiring patterns has a considerably high aspect ratio, such methods may have a limited ability to fill the gap with a silicon oxide. According to the need for more simple method, HDP-CVD has been recently developed as a gap-filling method.

HDP-CVD uses an electric field and/or a magnetic field to form a high density of plasma ion, thereby decomposing a source gas and depositing it in a thin film form on a substrate. HDP-CVD has a higher ionization efficiency than another type of CVD (e.g., Plasma Enhanced Chemical Vapor Deposition). Both a main power for forming a higher density of plasma ion and a DC bias power for accelerating an inert gas are applied at the same time during HDP-CVD process. In addition, HDP-CVD can carry out both a depositing process and an etching process in situ. Especially, an etching reaction can be concentrated in a region of a large arrival angle in a surface morphology of a substrate, so that a tapered shape of gap can be maintained. Therefore, HDP-CVD has a superior gap-filling ability, compared with another type of CVD.

However, a HDP-CVD process having distinctive advantages as discussed above has also serious disadvantages as follows.

Firstly, the HDP-CVD process may produce or result in a problem where a metal wiring corrodes at an initial stage thereof, because the ratio of a depositing rate to an etching rate becomes unstable according to a surface morphology of a substrate. In order to solve such a problem, before the HDP-CVD process is performed, an oxide liner based on silane (SiH₄) can be formed on a metal wiring using PECVD.

On the other hand, when the oxide liner is formed, an overhang may occur, which can deteriorate a gap-filling ability of HDP-CVD. Nevertheless, in order to prevent corrosion of a metal wiring, it is necessary to form a considerably thick oxide liner. Moreover, applying an exceedingly high bias power for removing the overhang and improving the gap-filling ability can also produce corrosion of the metal wiring.

Secondly, the HDP-CVD process has a lower growth rate or throughput of a thin film than another type of CVD, because both a depositing process and an etching process are carried out at the same time. Accordingly, the HDP-CVD process is mainly used for only gap-filling, and another process (e.g., PECVD) having a relatively high depositing rate is additionally adapted for a bulk deposition of a thin film. As a result, a conventional method for forming an intermetal dielectric layer generally has a number of processes and a very long processing time, because it generally includes both a HDP-CVD process for gap-filling and a PECVD process for a bulk deposition

Furthermore, a conventional method for forming an intermetal dielectric layer includes the steps of: gap-filling a HDP-CVD oxide; capping the HDP-CVD oxide with a PECVD oxide; and planarizing the PECVD oxide. Here, because the system must be maintained in a vacuum state even during non-processed period between such processing steps, manufacturing costs and time can be unnecessarily increased.

### SUMMARY OF THE INVENTION

It is, therefore, an object of the present invention to provide a method for forming an intermetal dielectric layer having a superior gap-fill property, by using a nitride liner able to effectively protect corrosion of a metal wiring during a HDP-CVD process.

Another object of the present invention is to provide a method for forming an intermetal dielectric layer, thereby enabling improvement of both a gap-filling property and a throughput of deposition.

To achieve the above objects, an embodiment of a method for forming an intermetal dielectric layer of a semiconductor device using high density plasma chemical vapor deposition (HDP-CVD), according to the present invention, comprises the steps of: (a) forming a metal wiring including at least one via-hole by patterning a metal layer formed on a semiconductor substrate; (b) forming a nitride liner protecting the metal wiring; and (c) forming the intermetal dielectric layer on and between the metal wiring using HDP-CVD. Here, the nitride liner is preferably formed to cover profiles of the metal wiring and a portion of the substrate exposed through the at least one via-hole.

In addition, step (c) preferably comprises the steps of: (c1) forming a gap-fill oxide for gap-filling the at least one via-hole; and (c2) forming a first capping oxide on the gap-fill oxide. Especially, step (c1) is performed under conditions of: applying a relatively high bias power at an initial HDP-CVD process to prevent an overhang from occurring on a top corner of the metal wiring; then improving a ratio of depositing rate to an etching rate by gradually decreasing the bias power until sufficiently forming the gap-fill oxide. In addition, forming the first capping oxide in step (c2) can be performed under an unbiased power condition after the gap-fill oxide is completely formed. Furthermore, step (c) further includes the step of (c3) planarizing the first capping oxide by sputtering under the condition of applying only bias power during the HDP-CVD process. In addition, step (c) further includes the steps of: (c4) forming a second capping oxide on the first capping oxide using the HDP-CVD; and (c5) planarizing the second capping oxide by chemical and mechanical polishing (CMP). Forming the second capping oxide in step (c4) is performed under an unbiased power condition during the HDP-CVD process.

In addition, a semiconductor device with an intermetal dielectric layer, according to the present invention, comprises: at least one metal wiring including at least one via-hole; a nitride liner protecting the at least one metal wiring; and an intermetal dielectric layer formed on the nitride liner by high density plasma chemical vapor deposition (HDP-CVD). Preferably, the nitride liner covers profiles of the metal wiring. Furthermore, the intermetal dielectric layer can include: a gap-fill oxide formed on the nitride liner by the HDP-CVD; and a first capping oxide formed on the gap-fill oxide after the gap-fill oxide is completely formed. In addition, the intermetal dielectric layer further includes a second capping oxide formed on the first capping oxide under an unbiased power condition during the HDP-CVD process.

These and other aspects of the invention will become evident by reference to the following description of the invention, often referring to the accompanying drawings.

### BRIEF DESCRIPTION OF DRAWINGS

FIGS. 1 to 6 are cross-sectional views illustrating an embodiment of a method for forming an intermetal dielectric layer in a semiconductor device using HDP-CVD according to the present invention.

### DETAILED DESCRIPTION OF THE INVENTION

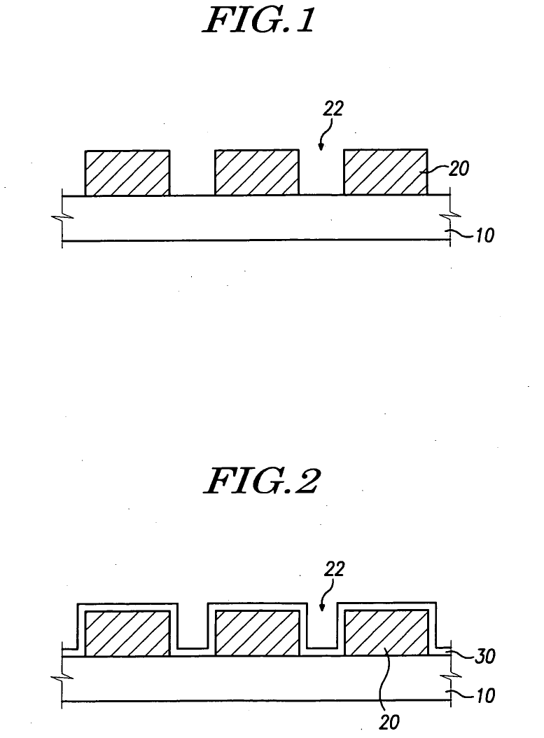

Hereinafter, an embodiment of a method for forming an intermetal dielectric layer of a semiconductor device using high density plasma chemical vapor deposition (HDP-CVD), according to the present invention, will be described with reference to FIGS. 1 to 6.

First, as shown in FIG. 1, a metal wiring 20 is formed on a semiconductor substrate 10 such as a silicon wafer on which one or more sub-layers are formed in advance. The metal wiring 20 can be formed in a manner known to those skilled in the art, for example, by forming a metal layer on the substrate 10, then etching or patterning the metal layer using a photoresist pattern. The metal wiring 20 includes at least one via-hole 22 exposing a portion of the substrate 10.

Next, before a gap-filling process of the HDP-CVD process, a nitride liner 30 is formed on the metal wiring 20 and an exposed portion of the substrate 10, as shown in FIG. 2. The nitride liner 30 has a higher tolerance to the etch than a conventional oxide liner, and prevents corrosion of the metal wiring 20 due to plasma ions during HDP-CVD process. In addition, the nitride liner 30 can be formed in such a manner as plasma-enhanced chemical vapor deposition (PECVD), as well as HDP-CVD.

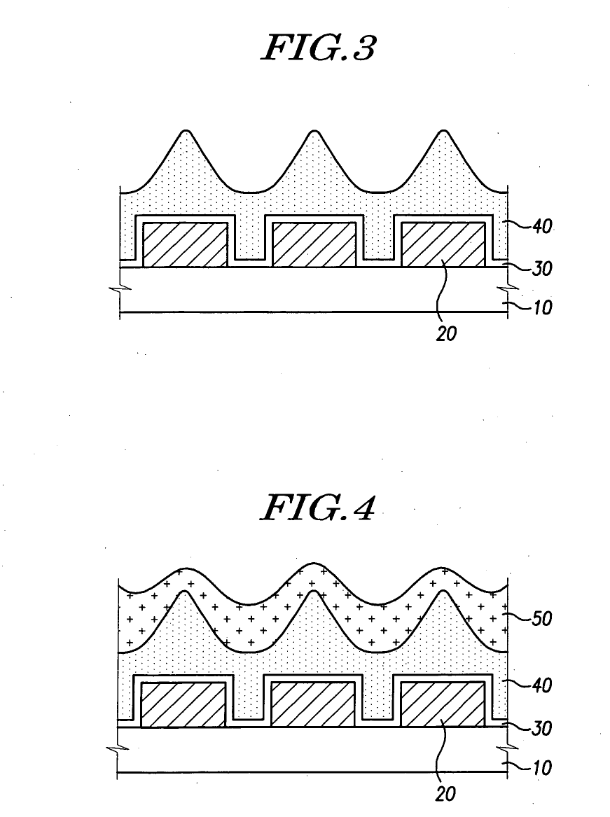

Continuously, the substrate 10 with the metal wiring 20 and the nitride liner 30 undergoes a HDP-CVD process able to carry out both depositing and etching in situ. A series of steps for forming an intermetal dielectric layer by the HDP-CVD process will be described in detail with reference to FIGS. 3 to 6.

Referring to FIG. 3, at an initial HDP-CVD process, gap-filling of a silicon oxide in via-holes 22 is performed under the condition of applying a relatively higher bias power than in a conventional HDP-CVD process. In general, the HDP-CVD process can be controlled using two types of power. One is a main power for forming plasma ion and the other is a bias power for accelerating an inert gas. The main power influences a depositing reaction, and the bias power influences an etching reaction. The above initial HDP-CVD condition means that an etching reaction by the bias power becomes more dominant than a depositing reaction by the main power. Thus, a deposition of an oxide (i.e., an overhang) on a top corner of the metal wiring 20 can be prevented. Even if a higher bias power is applied, corrosion of the metal wiring 20 can be prevented because the nitride liner 30 protects the metal wiring 20.

Then, the bias power of the HDP-CVD process is gradually decreased according to the gap-filled amount in via-holes 22, until a gap-fill oxide 40 is completely formed (i.e., until via-holes 22 becomes sufficiently filled with the gap-fill oxide 40). When the bias power becomes decreased, a ratio of a depositing rate to an etching rate becomes increased so that a gap-filling rate becomes improved.

After via-holes 22 are sufficiently filled with the gap-fill oxide 40, a first capping oxide 50 is deposited under an unbiased power condition by a HDP-CVD process, as shown in FIG. 4, while it is deposited by PECVD in the conventional method. Here, the unbiased power condition means a state in which a bias power is not applied. HDP-CVD process under no bias power condition would not carry out an etching process but a depositing process, thus enabling improvement of a depositing rate of the first capping oxide 50.

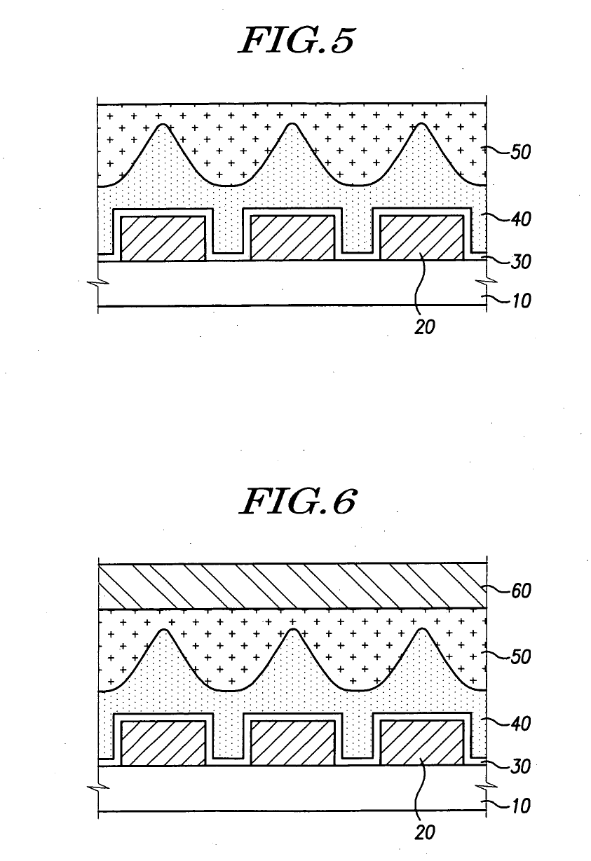

Meanwhile, the completely deposited first capping oxide 50 over the metal wiring 20 generally has a mountain-shaped surface profile as shown in FIG. 4. The mountain-shaped surface profile of the first capping oxide 50 can be also planarized by the a HDP-CVD process, as shown in FIG. 5. Namely, applying only a bias power (without a main power) during the HDP-CVD process can make a sputtering etch further dominant relative to a depositing process, thus enabling planarization of the first capping oxide 50 by etching or removing protruded portions thereof.

Referring to FIG. 6, a second capping oxide 60 is preferably formed on the first capping oxide 50 using the HDP-CVD process without applying a bias power, in order for a depositing process to be dominant.

In addition, the second capping oxide 60 can be planarized by chemical and mechanical polishing (CMP) and/or a HDP-CVD sputtering process. The second capping oxide 60 can be formed to have a further planarized surface profile by adapting both a HDP-CVD sputtering process and CMP.

On the other hand, the first capping oxide 50 can be formed to have a larger thickness, and planarized by CMP without undergoing the HDP-CVD sputtering process. Thus, a sufficiently thick intermetal dielectric layer can be formed without the second capping oxide 60.

According to the present invention, it is possible to manufacture a semiconductor device having a superior gap-fill property, by using a nitride liner able to effectively protect corrosion of a metal wiring during a HDP-CVD process.

In addition, in a method according to the present invention, the gradual control of the bias power of HDP-CVD can improve a depositing rate of an oxide, thus enabling improvement of both a gap-filling ability and a throughput of deposition.

In addition, according to the present invention, it is possible to form an intermetal dielectric layer in a semiconductor device by only using a HDP-CVD process. Therefore, the number of necessary steps for forming the intermetal dielectric layer can be minimized.

While the invention has been shown and described with reference to certain preferred embodiments thereof, it will be understood by those skilled in the art that various changes in form and details may be made therein without departing from the spirit and scope of the invention as defined by the appended claims.

What is claimed is:

1. A method for forming an intermetal dielectric layer of a semiconductor device using high density plasma chemical vapor deposition (HDP-CVD), said method comprising the steps of:
(a) forming a metal wiring including at least one via-hole by patterning a metal layer formed on a semiconductor substrate;
(b) forming a nitride liner protecting the metal wiring; and
(c) forming the intermetal dielectric layer on and between the metal wiring using the HDP-CVD.

2. The method of claim 1, wherein the nitride liner is formed to cover profiles of the metal wiring and a portion of the substrate exposed through the at least one via-hole.

3. The method of claim 1, wherein step (c) comprises the steps of: (c1) forming a gap-fill oxide for filling the at least one via-hole; and (c2) forming a first capping oxide on the gap-fill oxide.

4. The method of claim 3, wherein step (c1) is performed under conditions of: applying a relatively high bias power at an initial HDP-CVD process to prevent an overhang from occurring on a top corner of the metal wiring; and improving a ratio of depositing rate to an etching rate by gradually decreasing the bias power until sufficiently forming the gap-fill oxide.

5. The method of claim 3, wherein forming the first capping oxide in step (c2) is performed under an unbiased power condition after the gap-fill oxide is completely formed.

6. The method of claim 3, wherein step (c) further includes the step of (c3) planarizing the first capping oxide by sputtering under the condition of applying only bias power during the HDP-CVD process.

7. The method of claim 3, wherein step (c) further includes the steps. of: (c3) forming a second capping oxide on the first capping oxide using the HDP-CVD; and (c4) planarizing the second capping oxide by chemical and mechanical polishing (CMP).

8. The method of claim 7, wherein forming the second capping oxide in step (c3) is performed under an unbiased power condition during the HDP-CVD process.

9. A semiconductor device with an intermetal dielectric layer formed by a method of claim 1, comprising:
at least one metal wiring including at least one via-hole;
a nitride liner protecting the at least one metal wiring; and
an intermetal dielectric layer formed on the nitride liner by high density plasma chemical vapor deposition (HDP-CVD).

10. The device of claim 9, wherein the nitride liner covers profiles of the metal wiring.

11. The device of claim 9, wherein the intermetal dielectric layer includes: a gap-fill oxide formed on the nitride liner by the HDP-CVD; and a first capping oxide formed on the gap-fill oxide after the gap-fill oxide is completely formed.

12. The device of claim 11, wherein the intermetal dielectric layer further includes a second capping oxide formed on the first capping oxide under an unbiased power condition during the HDP-CVD process.
